(19) United States
(12) Patent Application Publication
(10) Pub. No.: US 2025/0155488 A1
(43) Pub. Date: May 15, 2025

(54) COMPUTER-IMPLEMENTED METHOD FOR EVALUATING THE STATE OF A SURGE ARRESTER

(71) Applicant: Tridelta Meidensha GMBH, Hermsdorf (DE)

(72) Inventors: Phillip Raschke, Hermsdorf (DE); Sinclair Junior Jontzo Fotsing, Hermsdorf (DE)

(21) Appl. No.: 18/944,356

(22) Filed: Nov. 12, 2024

(30) Foreign Application Priority Data
Nov. 10, 2023 (DE) 102023131313.4

(51) Int. Cl. G01R 31/12; G01R 31/52

(52) U.S. Cl. CPC G01R 31/1236; G01R 31/52

(57) ABSTRACT

The invention relates to a computer-implemented method for monitoring the status and evaluating the behavior of a surge arrester, the method comprising the following steps: providing measured values (S10) of one or more surge arresters; standardizing the provided measured values (S12); extracting parameters (S14) for characterizing each surge arrester from the standardized measurement values; determining a state of each surge arrester (S16) using a machine learning algorithm; and outputting an operating recommendation for each surge arrester (S18) based on the determined state of the surge arrester. (FIG. 1)

The invention relates to a method for evaluating the states of surge arresters based on their creepage current and leakage current.

A surge arrester, also referred to as a surge protection device, is used in electrical energy transmission and distribution systems to protect devices connected to these systems from damages caused by surges due to lightning or switching operations in the network.

Typically, a surge arrester uses varistors to perform its function. Varistors can be zinc-oxide components with non-linear electrical resistance characteristics. This means that their resistance decreases sharply when a threshold value is exceeded. This property allows the surge arrester to quickly and effectively conduct the surge to the ground. The surge arrester is usually connected between the conductor and ground for this purpose. In the event of overvoltage, the surge arrester safely diverts the excess energy to ground, thereby limiting the line voltage to a value that does not exceed the insulation values of the connected power technology, while isolating the lines from ground at normal operating voltages.

Surge arresters are designed to operate below their maximum continuous operating voltage (Uc) during normal operation, thus exhibiting high resistance and allowing only a small leakage current to flow through the active part of the surge arrester. Surge arresters are usually dimensioned so that the leakage current does not cause excessive power loss or exceed a certain limit during normal operation.

However, a brief or continuous excess load on the surge arrester, a faulty design of the field control elements or the use of zinc oxide varistors that do not have long-term stability can lead to a degradation of the varistors, whereby the U-I (voltage-current) characteristic curve of the surge arrester drops suddenly or also successively and a higher leakage current thus flows in the new operating point. The power loss is radiated from the surge arrester enclosure in the form of heat energy. If the electrical energy introduced into the arrester by the continuously flowing leakage current and by additional transient overvoltages exceeds the heat energy that can be radiated from the arrester to the outside, the arrester becomes thermally unstable and fails electrically. This is a fault that occurs only rarely.

Most surge arrester failures are due to moisture penetration. This usually occurs either through defective sealing systems in surge arresters with gas volumes or, as is the case with directly cast polymer arresters or other arresters without gas volumes, directly through the interface between the different materials. Possible causes of such a failure include, for example, errors in the manufacturing process, material fatigue or design weaknesses. In the case of surge arresters with an enclosed gas volume, it is usually a lengthy process in which moisture enters through a leak due to an alternating pressure difference between the interior and exterior of the surge arrester. When the temperature inside the enclosure drops below the dew point, moisture condenses along the active part or along the inner surge arrester housing. This can lead to flashovers and the formation of creepage currents inside the housing, which can ultimately result in a complete short circuit inside the housing and thus in the sudden failure of the arrester.

Another common failure mode is a deterioration of the insulating properties of the arrester housing caused by surface contamination in the form of increased surface conductivity, tracking and erosion. This is a common problem with surge arresters used in so-called pollution areas. These surge arresters show deposits of conductive sediments after a certain time. This causes creepage currents and initially partial flashovers along the surface of the housing, which can damage the housing of the surge arrester or impair the hydrophobic properties of silicone-insulated surge arresters. In addition, only partially conductive housing sections can cause a high radial field between the varistor column and the outer layer of contamination, causing partial discharges and thus damage inside the housing. If this contamination is detected early, it can be remedied by cleaning the surface. Otherwise, the contamination could lead to an external flashover and permanent damage to the surge arrester.

In view of the many different causes of failure in surge arresters, operators of power systems are faced with the challenge of dealing with aging equipment. As a result, the topic of “asset life cycle management” is becoming a focus of attention in the energy sector. To meet this challenge, manufacturers of power engineering equipment offer monitoring systems that have been developed specifically for their products. For example, DE 10 2015 013 433.7 discloses such a monitoring system for surge arresters. A similar concept is described in:
https://p3.aprimocdn.net/siemensenergy/fb8f300d-debc-415c-87e6-b03b01315915/Sensarrester-flyer-with-Frost-Sullivan-Award-pdf_Original % 20file.pdf.

These monitoring systems monitor a variety of devices, such as transformers, switches, disconnectors, converters, lines, isolators and surge arresters, resulting in a large amount of data. However, this data is usually so abstract that it is necessary to have a specialist for each field of application to evaluate it.

The large amount of data and experience, in particular the measurement data from surge arresters, requires careful evaluation because the information content is not readily apparent. As a result, many operators of power systems are unable to assess the condition or remaining lifespan of such devices.

To make matters worse, a power system operator usually uses a large number of surge arresters of different types, from different years of manufacture, and from different manufacturers. An overview of the various basic designs can be found, for example, at:
https://cache.industry.siemens.com/dl/files/132/109747132/att_918329/v1/Metalloxid-Ableiter_in_Hochspannungsnetzen _-_ Grundlagen.pdf.

Well-known management strategies require that alarms be integrated into existing systems, which send notifications when the typical leakage current limits of the surge arrester are exceeded. However, for complex signal patterns that could enable predictions about future failures, the operator must contact a specialist to request manual evaluations of the surge arrester's condition.

In light of this, the object of the invention is to propose a method by which the collected data can be used to automatically assess operating conditions to better predict the further behavior of surge arresters, to service or replace them in a timely manner, and to prevent damage or sudden failure due to a surge arrester defect.

The task is solved by the subject matter of the independent claims.

According to a first aspect of the invention, this task is solved by a computer-implemented method for determining the operating state of a surge arrester, wherein the method comprises the following steps:
providing measurement values of at least one surge arrester;
standardizing the provided measurement values;
extracting parameters for characterizing the at least one surge arrester from the standardized measurement values;
determining a state of the at least one surge arrester using a machine learning algorithm; outputting a recommendation for operating the at least one surge arrester.

The measured values, such as the peak value of the leakage current and/or the resistive current based on the third harmonic of the leakage current, can preferably be segmented time series that are determined at a surge arrester using a corresponding sensor, in particular a current measuring device. The data obtained in this way in the measured time series can be segmented particularly preferably in appropriate windows to be used later for a window-based analysis.

The measured values of the different surge arresters can have different orders of magnitude, which is due to the monitored surge arrester and the respective use case. The signals are standardized for better interpretability and comparability of the data. For example, a z-scope standardization method can be used for standardization, which transforms the measured values to a distribution with a mean of 0 and a standard deviation of 1. The dynamic behavior of the data is preserved, and the unit becomes dimensionless.

In some cases, normalization can precede standardization. The main difference between data normalization and data standardization is that data normalization brings the data into a specific scale. The goal of this method is to adjust the data so that the data has the same range of values. This makes it possible to compare data with different scales or units.

Standardization, on the other hand, transforms the data to a standard normal distribution. This removes the mean and scales the data to unit variance. The goal of standardization is to bring the data into a standardized form that allows the range of the data to be retained and the distribution of the values to be the same. This makes the measured values of different surge arresters comparable.

Characteristic quantities are then extracted from the standardized data and used to evaluate the behavior of the surge arrester. With the help of various feature extraction methods, a large number of features can easily be obtained, which have advantages and disadvantages. On the one hand, a high number of features used increases the accuracy and depth of the analysis. On the other hand, the various features can often contain redundant information, which can have a negative effect on the learning of learning algorithms. This can make the models unstable.

Depending on the different patterns in the measured values, various features can be extracted from the measured values. The patterns found in the measured values can be roughly divided into weather-related signal patterns, grid-related patterns and surge arrester malfunction patterns. Weather-related and grid-related patterns are irrelevant for evaluating the state of the arrester.

In the event of a network interruption due to failures or maintenance work, the leakage current values usually show a value close to 0 μA. If an earth fault occurs in a network with an isolated zero conductor (star connection), the affected line is drawn to almost earth potential, causing the voltage at the surge arrester to drop considerably and the leakage current to decrease.

The other two phases of the network assume the chained voltage value, which leads to an increase in the leakage current, as can also be observed, for example, in weather-related signal patterns. The surge arresters are usually installed outdoors and are affected by various weather conditions such as rain, fog, humidity and solar radiation. Both phenomena show similar patterns in the measured values, but they are not dependent on the state of the arrester and must be separated from the user data before feature extraction.

The surge arresters with malfunction show different signal patterns depending on the type and severity of the error. The malfunction can be subdivided, for example, into strongly periodically pulsed signal patterns, very strongly stochastically fluctuating signal patterns or a trend increase of the signal.

The main objective of the extraction of characteristic quantities is to replace the large amount of data with a few meaningful extracted characteristic quantities that contain all the necessary information to solve the problem under investigation. Therefore, the characteristic quantities that best characterize the surge arrester are extracted from the available database.

Once the parameters for the surge arrester have been determined, a state of the surge arrester is determined from them. A machine learning algorithm is used for this purpose.

A machine learning algorithm can assume various forms, such as linear models, decision trees, support vector machines, neural networks, and many others. It is optimized by learning from training data, recognizing signal patterns and rules to make the best possible predictions or classifications for new data.

The effectiveness of a machine learning algorithm depends on various factors, including the quality and quantity of the training data, the choice of model, the model configuration, and the evaluation of the model using evaluation metrics. The model can be continuously improved and optimized to maximize accuracy and performance.

The linear regression model assumes a linear relationship between a dependent variable and one or more independent variables and is used to make predictions on continuous values.

Support Vector Machines (SVM) is a model that is often used for classification or regression that detects signal patterns in the data. It searches for the optimal separation between different classes or attempts to fit a continuous function to the data.

Decision trees are models that create decision rules in the form of a tree diagram. They are used to divide data into features and enable predictions or classifications.

Naive Bayes is a probabilistic model based on Bayes' theorem that is used for classification. It assumes that features are independent of each other and calculates the probability of a particular class based on the given features.

Neural networks are models that are preferably used for processing images or other matrix-based data. The architecture of a neural network comprises several nots, neurons or nodes, which are arranged in layers. Several layers can also be designed as subnetworks. Subnetworks can also share one or more layers to solve their tasks with the same output values. After that, each subnetwork can have its own layers that only serve to solve the specific task of the subnetwork.

Preferably, machine learning algorithms based on clustering methods are used to carry out the proposed procedure. In clustering, the data is divided into groups that are most similar to each other. In particular, this can be a model that performs a partitioning cluster analysis. The aim of this is to divide the data of the training data set into a number of groups that is determined at the outset. This division is optimized iteratively until a target function, such as the mean square error, reaches an optimum. The common methods of this form are, for example, the K-means, K-medoids and CLARANS procedures.

A recommendation for the further operation of the surge arrester can be derived from the state of the surge arrester. For example, a surge arrester that is classified in a class representing severe weathering can be classified as less reliable. The operator can then maintain, repair or replace the surge arrester to prevent damage or unplanned failure of the surge arrester. In another case, a surge arrester can, for example, be categorized in a clear error class, where the severity of the error is only slight, so that the probability of failure is just as low. This does not result in any direct actions for the operator and the surge arrester can remain in operation.

Preferably, surge arresters can be divided into different classes, which are assigned to weather-related conditions, usage-related conditions and fault conditions. In embodiments, further subclasses can be used to describe the degree of the respective condition in more detail.

In one embodiment, the standardization of the provided measurement values is preceded by a smoothing of the provided measurement values.

The smoothing of the measurement values has the advantageous effect of minimizing the influence of extreme values on the remaining measurement values.

In one embodiment, the standardization of the provided measurement values is preceded by the removal of the “off-states” from the provided measurement values.

The off-states indicate the periods during which the lines are de-energized or an earth fault has occurred, causing the leakage current to be almost 0. These low values can be identified and removed from the measurement values using the so-called “box plot” method, for example.

No information regarding the state of the surge arrester can be obtained from the measured values of the off states. Therefore, reducing the measured values around the off states reduces the computational effort for the machine learning algorithm and increases the efficiency with which the characteristics are determined.

In one embodiment, the measurement data is acquired by measuring the leakage current in the surge arrester, whereby a peak current and a resistive current are determined from the leakage current.

The leakage current in a surge arrester consists of a sinusoidal capacitive component, which is phase-shifted by −90° to the voltage signal, and a resistive component, which is in phase with the voltage signal and in the form of a periodic pulse signal.

These two components combine to form the total leakage current, from which two important core values can be extracted. The peak value of the leakage current and the third harmonic in relation to the mains frequency of 50 or 60 Hz. The peak value of the leakage current always depends on the predominant current component, capacitive or resistive. At low voltage levels (U<Uc), the peak current assumes the peak value of the capacitive component. At higher voltage levels, mainly above the rated voltage (Ur), the peak current is based on the peak value of the resistive component.

The resistive current is particularly meaningful for evaluating the surge arrester in relation to the capacitive current, since the former changes significantly when the current-voltage characteristic of the surge arrester deteriorates. In such a case, the capacitive current does not change significantly.

However, for optimal monitoring of the surge arrester condition, it is advantageous to monitor both components of the leakage current in the surge arrester.

One method for measuring the leakage current is based on the fact that the non-linear current-voltage characteristic of the surge arrester generates harmonics in the leakage current. The proportion of harmonics in the leakage current depends heavily on the peak value of the resistive current and the operating point, and thus varies with the voltage and the temperature of the surge arrester. Experience has shown that the resistive current can be described by the third harmonic using a factor. For example, the total leakage current can be obtained periodically—about once an hour—from the measured values over 10 wavelengths at the usual line voltage of 50 or 60 Hz.

For the evaluation of the resistive current, the third harmonic is the most common. This offers the best measurement sensitivity.

The leakage current with the components of peak current and resistive current advantageously forms a measurable variable that is relatively easy to determine and from which good characteristic variables can be derived.

In one embodiment, the extraction of the characteristics involves a transformation of the standardized measurement values into a frequency spectrum, wherein the characteristics include discrete spectral components from the frequency spectrum and a trend of the frequency spectrum.

Waveform data can be analyzed in the time domain, in the frequency domain, and in the time-frequency domain. Each of these approaches offers different insights and makes it possible to examine various aspects of the data.

Time domain analysis directly considers the measured values in their temporal progression. The signal behavior is examined on the basis of parameters such as signal pattern, signal trend, periodicity and other important signal properties such as stationarity or non-stationarity. While stationary signals are characterized by the invariable statistical properties such as mean value, variance and auto-correlation over time, the statistical properties of a non-stationary signal change over time.

Many time series analysis methods are only suitable for stationary measurement series. However, the signals analyzed using the proposed method may not be stationary because the monitored surge arresters are exposed to many external influences that affect their signal patterns.

Non-stationary signals can be treated as stationary by windowing. Special procedures can be applied to transform the signals into stationary signals. Time domain analysis is particularly suitable for detecting signal patterns or changes in the dynamic behavior of the measurement sequence over time. It is possible, for example, to identify anomalies or threshold changes.

For example, the behavior of a surge arrester is influenced by the course of the day, i.e. the temperature differences between day and night.

The frequency domain analysis looks at the frequency components of a time series by breaking the signal down into its spectral contents. This involves analyzing the amplitudes, phase relationships and main frequencies of the signal.

There are methods to transform signals from the time domain to the frequency domain and vice versa. The fast Fourier transform (FFT) is a commonly used method. This method allows the frequency-specific energy and phase dynamics of a signal to be examined or can be used as an aid for various filter or convolution algorithms.

The FFT is well suited for stationary signals, since the relevant characteristics of the signal can be derived in the time domain. Non-stationary signals have power spectra that can be difficult to interpret, for which the classic FFT function is severely limited. The Welch method, on the other hand, divides the non-stationary signal into successive windows, performs the Fourier transform for each window, and averages the power spectra.

Due to the fact that the measured values of different surge arresters can include complicated signals whose dynamic behavior changes completely over time due to occurring error states or weather influences, an exclusive consideration in the time domain is not always sufficient. Therefore, methods can be implemented to supplement this, which capture the entire dynamic behavior and, consequently, its changes. FFT and DWT are suitable methods for mapping this dynamic behavior in the frequency domain.

In particular, a discrete spectral component with 1/day and/or 2/day or a week in the peak current can be used to characterize surge arresters. Seasonal observations over longer periods are also possible.

An emphasis of the spectral component of 1/day indicates a connection with daily processes, for example, condensation in the morning and the resulting high surface currents. Surface currents are regularly caused by moisture and increase with the layer of dirt. In addition, a normal operating condition can also be characterized by the 1/T behavior because the line voltage usually takes on a similar load-dependent daily course.

The discrete spectral component with 2/day in the peak current can indicate a correlation with daily processes, for example, soiling and condensation in the morning and condensation in the evening and the resulting high surface current.

Furthermore, higher harmonics of the discrete spectral components of the peak current can be used. These higher harmonics can depict seasonally recurring behavior, for example over the course of a day. If there is no noise in higher spectral ranges and thus no stochastic behavior, i.e. a 1/f behavior, this can be interpreted as the presence of recurring environmental influences that are linked to a time of day, such as heavy rainfall in monsoon areas or similar.

In one embodiment, a comparison is made between the signal energy in one or more low-frequency ranges of the measurement series and in one or more higher-frequency ranges, and this is used to determine whether stochastic behavior is present or not.

In one embodiment, the characteristics also include a signal-to-noise ratio in the frequency spectrum, in particular in a defined section of the frequency spectrum.

In one embodiment, the parameters also include a trend of the frequency spectrum.

A slope in the range m≈0 in the spectrum can occur if the signal is subject to stochastic noise and all spectral components are weighted equally. This behavior can be observed in particular in surge arresters that have moisture inside. This is because small conductive paths are created that dry immediately due to the high current flow and the vaporized water condenses elsewhere.

In one embodiment, the parameters also include a trend in the time domain.

A rising trend m>0 in the time domain indicates an intensifying dynamic in the signal or a continuously increasing peak current and resistive current. All types of fault can manifest themselves in the time domain with a rising trend. A rising trend is therefore an indication of the presence of a fault. However, this characteristic is less suitable for identifying a specific fault. An exception to this, however, may be advanced ageing of the surge arrester, because in this case the values continuously increase and the signal has little energy.

In one embodiment, the characteristics further include a correlation value between the peak current and the resistive current in the time domain.

The inventors have determined experimentally that the correlation between the peak current and the resistive current, as well as the analysis of these two signals in the frequency domain, was useful for identifying the state of the surge arrester.

The correlation between the peak current and the resistive current is high when strong surface currents are present. The resistive component of the leakage current, which is extracted from the third harmonic leakage current components, increases equally, because harmonic components are added to the current by brief dry-band discharges. However, this also applies to internal currents caused by moisture ingress where partially dry surfaces flash over. The resulting partial short circuits of the varistor blocks generate high peaks in the resistive current, which exceed the capacitive current component and thus determine the peak current. A strong correlation between the resistive current and the peak current, especially greater than 0.5, can indicate heavy contamination or severe moisture ingress. If the correlation is low, especially close to 0, it can be concluded that there is no or only slight surface contamination or no malfunction.

The determination of the correlation coefficient between the peak current and the resistive current in the segmented window can be used. For example, the Pearson correlation coefficient can be used for this.

The characteristic quantities described can preferably be used together and/or in groups.

In one embodiment, the leakage current is determined during operation of the surge arrester.

This advantageously enables the surge arresters to be checked for malfunctioning, preferably at regular intervals, and to be serviced, repaired or replaced depending on the assessment. For this purpose, the surge arresters can be equipped with devices that transmit the measured values to a central evaluation system.

In a further embodiment, the measured values can be collected over a defined period of time and then evaluated in a bundled form. This means that the continuous transmission of the measured values to the central evaluation system can be limited to a few transmissions, for example, supported by the transport of data carriers.

In a further aspect, the invention relates to a computer program with program code for carrying out a method as described above when the computer program is executed on a computer.

In a further aspect, the invention relates to a computer-readable data carrier with program code of a computer program for carrying out a method as described above when the computer program is executed on a computer.

In a further aspect, the invention relates to a system for evaluating the behavior of a surge arrester, wherein the system is designed to carry out a method as described above.

For example, the system can be implemented as a web server with a web application, as a local computing system, or as a portable device for checking surge arresters on site.

The described embodiments and further developments can be combined with each other in any way.

The accompanying drawings are intended to provide further understanding of the embodiments of the invention. They illustrate embodiments and, in connection with the description, serve to explain the principles and concepts of the invention.

Showing:

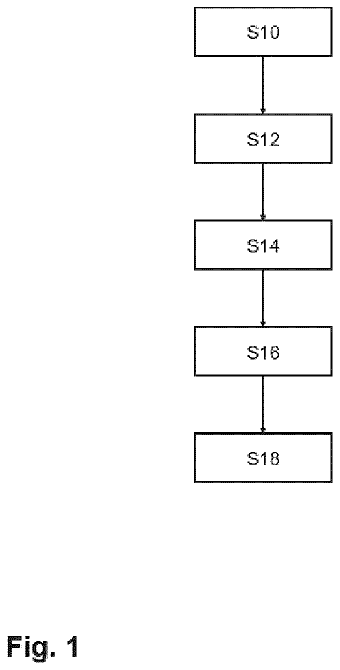

FIG. 1 schematically the sequence of a method according to one embodiment; and

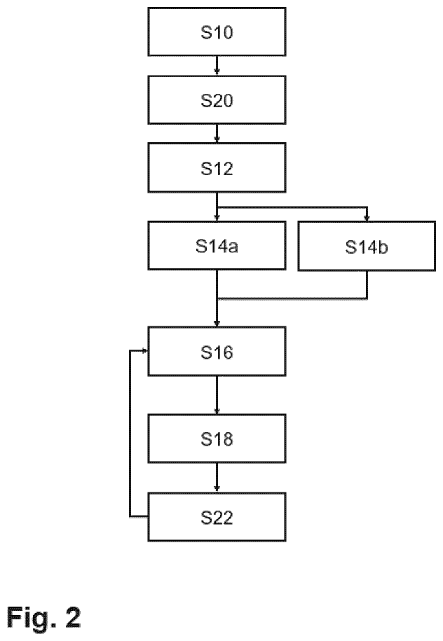

FIG. 2 schematically the sequence of a method according to a further embodiment.

FIG. 1 schematically shows a simplified sequence of the method according to one embodiment.

The method begins in step S10 by providing the measured values of a surge arrester. The measured values can be recorded and evaluated continuously or collected and evaluated in batches. For example, the measured values can be transmitted from the surge arresters to a data processing system via a network, in particular a radio network. The data processing system can be located at the operator's of the power engineering system or at the manufacturer's. The primary measured values are current measured values with a resolution far below the grid frequency. These primary measured values are collected over a sufficiently long period of time, for example 10 wave sequences, and stored. The primary measured values can be obtained continuously, but it is preferable to measure these values at periodic intervals so that a set of primary measured values is obtained approximately once an hour or once every 15 minutes.

The set of primary measured values is then used to obtain the peak current, the third harmonic of the leakage current (hereinafter often referred to as “leakage current” for the sake of simplicity) and, if applicable, further characteristic values or derived measured values, preferably in the measuring device itself. If the term “measured value” is used in the following, it regularly refers to one of the derived measured values, unless a primary measured value is explicitly referred to.

In a second step S12, the provided measured values are standardized. The purpose of the standardization is to make the measured values of the surge arrester under investigation comparable to the totality of surge arresters used to train the machine learning algorithm. In this process, the measured values are corrected for effects that result from the special configuration of the surge arrester being analyzed. The correction can take into account, for example, the type of surge arrester, its use, or the infrastructure surrounding it. In particular, the line voltage in relation to the arrester rated voltage, the ratio of the rated voltage to the reference voltage of the surge arrester, the type of varistor used, the manufacturing tolerance in the ZnO stacking process during the production of the surge arrester, the grounding conditions and/or the capacitive boundary conditions at the point of use can be taken into account. Furthermore, the measured values can be standardized with regard to the surge arrester enclosure, which is made of porcelain or plastic, the shield design and/or the location and its climatic conditions.

In step S14, characteristic quantities are derived from the standardized measured values. The characteristic quantities serve to recognize the state of the surge arrester. Various features resulting from the behavior of the surge arrester can be used as characteristic quantities. In particular, the leakage current (peak value or third harmonic) can be used as a measured value and the features determined from it can be used as characteristic quantities.

The parameters may include, but are not limited to, a 1/day discrete spectral component in the peak current, a 2/day discrete spectral component, the higher harmonics of the discrete spectral components, a decreasing trend (mf<0) in the discrete frequency spectrum of the peak current, the signal-to-noise ratio in the frequency spectrum, an increasing trend (mf>0) in the discrete frequency spectrum, the correlation between the peak current and the resistive current in the time domain and/or a trend mz in the time domain of the peak current and the peak current.

In step S16, a machine learning algorithm is used to determine a state of the surge arrester. To do this, the characteristic quantities are entered as input quantities into the machine learning algorithm. The machine learning algorithm has been trained to recognize the state of a surge arrester using training data. The training data includes the characteristic variables of a plurality of surge arresters in different situations and with different states.

In particular, a classification task can be associated with the determination of the state, in which the machine learning algorithm assigns the surge arrester to one of several classes based on its characteristic variables, with each class representing a state.

How the assignment is made depends on the selected model and its architecture. Different models are structured differently. In principle, any model that is suitable for classification tasks can be used. In this case, clustering is performed because no labeled data is available. The results are group formations, whereby further procedures (for classification) can be applied afterwards.

In a final step S18, the state and the expression of the state are reported with a corresponding recommendation for action or with an alarm.

In one embodiment, the surge arrester can be assigned to several states. For example, a first state can indicate a degree of contamination and a second state can indicate the condition of the seals in the surge arrester. The properties “housing dirty/not dirty” and “seal intact/not intact” are not mutually exclusive. Furthermore, the states can be output as parameters in a spectrum, so that, for example, a property of the surge arrester is quantified.

According to the invention, additional information can also be obtained from the synopsis of the measured values or characteristic parameters of a group of surge arresters that are installed in the immediate vicinity and each of which is assigned to one of the three phases of the network.

FIG. 2 shows a modification of the method from FIG. 1. The process flow of the method schematically shown in FIG. 2 according to a further embodiment also begins with the provision of derived measured values of a surge arrester in step S10.

Before standardization, the measured values are preprocessed in step S20. In particular, the preprocessing can include segmentation of the measured values in order to isolate individual signals. For example, a peak current and a resistive current can be determined from a measured leakage current. Furthermore, the measured values can be filtered in order to remove, for example, the noise of the measuring device or other extraneous noise.

After standardization in step S12, the characteristic quantities are extracted in steps S14a and S14b. To do this, the standardized measurement values are transformed into a frequency space. The characteristic quantities can then be extracted from the measurement values in the time domain in step S14a and the frequency spectrum in step S14b.

In this embodiment, the determination of the state in steps S16 and the output of a recommendation for action in step S18 can proceed as described for FIG. 1. However, following the evaluation in step S18, a validation of the evaluation can be carried out in step S22.

The evaluation can be validated, for example, by checking whether the conditions assigned to the surge arrester are actually present when the surge arrester is serviced as a result of the evaluation. For example, the degree of contamination of the housing or the humidity inside the surge arrester can be determined. In addition or as an alternative, samples can be taken to check the processing of the measured values with the machine learning algorithm.

Alternatively, one of the surge arresters intended for replacement according to the method of the invention can be returned to the manufacturer for a detailed examination in the laboratory.

The results of these investigations can then be fed back to train the system.

While current monitoring devices only use the primary measurement values of a surge arrester to output a simple “red-yellow-green” signal, by using machine learning and taking into account a large amount of measurement data from a wide variety of surge arresters in a wide variety of environments, the invention allows a much more accurate and reliable statement to be made about the condition of each individual surge arrester, without the need for a specialist to carry out a complicated individual evaluation themselves.

### REFERENCE SIGNS

S10 Providing measurement values
S12 Standardizing measurement values
S14 Extracting characteristic parameters
S14a extracting characteristic quantities from the time period
S14b extracting characteristic quantities from the frequency spectrum
S16 determining a state
S18 deriving a recommendation for action
S20 preprocessing the measured values
S22 validating the evaluation

We claim:

1. A computer-implemented method for evaluating the behavior of a surge arrester, the method comprising the following steps:
providing measured values (S10) of one or more surge arresters;
standardizing the provided measured values (S12);
extracting parameters (S14) for characterizing at least one surge arrester from the standardized measured values;
determining a state of the at least one surge arrester (S16) using a machine learning algorithm; and
outputting a recommendation for action (S18) for the operation of the at least one surge arrester.

2. A computer-implemented method according to claim 1, wherein the standardizing of the provided measured values (S12) is preceded by a smoothing of the provided measured values.

3. A computer-implemented method according to claim 1, wherein the standardizing of the provided measured values (S12) is preceded by a removal of off-states from the provided measured values.

4. A computer-implemented method according to claim 1, wherein the measured values are detected by measuring a leakage current in the surge arrester, a peak current and a resistive leakage current being determined from the leakage current.

5. A computer-implemented method according to claim 1, wherein the measured values are determined during the operation of the surge arrester.

6. A computer-implemented method according to claim 1, wherein the extracting a parameters. (814) comprises transformation of the standardized measured values into a frequency spectrum and wherein the parameters include characteristic quantities which comprise discrete spectral components from the frequency spectrum and/or a trend in the frequency spectrum of a peak current.

7. A computer-implemented method according to claim 6, wherein the characteristic quantities further comprise a signal-to-noise ratio in the frequency spectrum, in particular in a defined section of the frequency spectrum.

8. A computer-implemented method according to claim 6, wherein the characteristic quantities further comprise a correlation value between the peak current and a resistive current in a time domain.

9. A computer program comprising program code for carrying out a method according to claim 1, when the computer program is executed on a computer.

10. A system for issuing a recommendation for the operation of a surge arrester, wherein the system is configured to carry out a method according to claim 1.

11. A non-transitory computer readable medium storing instructions executable by an associated processor to perform a method for evaluating the behavior of a surge arrester, the method comprising:
receiving measured values from one or more surge arresters via a network connection, the measured values obtained at periodic intervals;
standardizing the measured values to generate standardized measured values;
deriving characteristic qualities from the standardized measured values to characterize at least one surge arrester, wherein the characteristic qualities include leakage current;
determining a state of the at least one surge arrester using a machine learning algorithm based upon the characteristic qualities, wherein the state comprises at least one of a seal of the surge arrester intact or not intact and/or the surge arrester is dirty or clean; and
outputting a recommendation for action for the operation of the at least one surge arrester based upon the determined state.

12. The method of claim 11, comprising determining a peak current and a resistive leakage current from the leakage current.

13. The method of claim 11, wherein determining the state further comprises determining a humidity of the surge arrester.

14. The method of claim 13, wherein the outputting the recommendation for action for the operation of the at least one surge arrester comprises recommending a service of the surge arrestor responsive to the state comprising a humidity over a humidity threshold.

15. The method of claim 11, wherein the outputting the recommendation for action for the operation of the at least one surge arrester comprises recommending a cleaning of the surge arrester responsive to the state comprising the surge arrester is dirty.

16. The method of claim 11, wherein the outputting the recommendation for action for the operation of the at least one surge arrester comprises recommending a seal change responsive to the state comprising the surge arrester is not intact.

17. The method of claim 11, the receiving measured values comprising receiving a temporal progression of at least one of signal pattern, signal trend, or periodicity.

18. The method of claim 11, the determining a state of the at least one surge arrester using the machine learning algorithm based upon comparing signal energy in one or more low-frequency ranges of the measured values and in one or more higher-frequency ranges of the measured values.

19. The method of claim 18, utilizing the signal energy in the one or more low-frequency ranges of the measured values and the signal energy in the one or more higher-frequency ranges of the measured values to determine whether stochastic behavior is present or not.

20. A system for issuing a recommendation for the operation of a surge arrester, the system comprising:
a computer having a processor configured to perform a predefined set of operations in response to receiving a corresponding input from at least one surge arrestor;
the processor receives measured values from one or more surge arresters via a network connection, the measured values obtained at periodic intervals;
the processor standardizes the measured values to generate standardized measured values;
the processor characteristic qualities are derived from the standardized measured values to characterize at least one surge arrester, wherein the characteristic qualities include leakage current;
the processor utilizes a machine learning algorithm to determine a state of the at least one surge arrester based upon the characteristic qualities, the machine algorithm trained on a plurality of surge protectors with known states, wherein the state comprises at least one of surge protector adequate or surge protector needs service; and
the processor generates a recommendation for action for the operation of the at least one surge arrester based upon the determined state.
